(19) United States
(12) Patent Application Publication
(10) Pub. No.: US 2025/0357141 A1
(43) Pub. Date: Nov. 20, 2025

(54) MANUFACTURING METHOD FOR NITRIDE SEMICONDUCTOR DEVICE

(71) Applicant: FUJI ELECTRIC CO., LTD., Kanagawa (JP)

(72) Inventor: Ryo TANAKA, Hino-city (JP)

(21) Appl. No.: 19/087,553

(22) Filed: Mar. 23, 2025

(30) Foreign Application Priority Data
May 20, 2024 (JP) 2024-081527

(51) Int. Cl. H01L 21/324; H01L 21/225; H10D 30/01

(52) U.S. Cl. CPC H01L 21/324; H01L 21/2258; H10D 30/025

(57) ABSTRACT

There is provided a manufacturing method for a nitride semiconductor device including: providing an amorphous protective film containing silicon above a nitride semiconductor layer; and performing heat treating on the nitride semiconductor layer provided with the protective film, under a pressure condition of 1 MPa or higher and 1 GPa or lower, and under a temperature condition of 1200° C. or higher and 1500° C. or lower. The protective film may be in contact with the nitride semiconductor layer. The protective film may contain at least one of SiO₂, SiN, or SION.

### BACKGROUND

### 1. Technical Field

The present invention relates to a manufacturing method for a nitride semiconductor device.

### 2. Related Art

Patent Document 1 describes that “a stacked body 60 which is to be processed and which includes a GaN layer 12 is annealed, for a certain period of time, at a temperature and a pressure that are predetermined” using a protective film “that is an AlN (aluminum nitride) film”. Patent Document 2 describes a manufacturing method for a nitride semiconductor device in which “SiO₂ is used as a cap layer 20” and that “heat treating is performed at 1200° C. or lower”. Patent Document 3 describes that a “nitride semiconductor layer 20 is heated at a temperature of 1200° C. or higher under an ammonia atmosphere and at a low pressure of less than 10 kPa” using an “amorphous protective film 42 for annealing”.

Patent Document 2 describes that “it should be noted that regardless of whether the cap layer 20 is provided, when the heat treating is performed on a stacked body 10 at a temperature higher than 1200° C., a crystal structure of a main surface 15 becomes rough”. In addition, Patent Document 3 describes that “when the annealing treating step is performed, the protective film 42 for annealing, which was amorphous, is crystallized”.

### PRIOR ART DOCUMENTS

### Patent Documents

Patent Document 1: Japanese Patent No. 6911281
Patent Document 2: Japanese Patent No. 6217719
Patent Document 3: International Publication No. WO 2021/161509

### BRIEF DESCRIPTION OF THE DRAWINGS

FIG. 1 shows an example of a cross section of an active region of a nitride semiconductor device 100.

FIG. 2 is a flowchart showing an example of a manufacturing method for the nitride semiconductor device of the present example.

FIG. 3A shows an example of a manufacturing method for the nitride semiconductor device 100 of the present example.

FIG. 3B shows an example of the manufacturing method for the nitride semiconductor device 100 of the present example.

FIG. 3C shows an example of the manufacturing method for the nitride semiconductor device 100 of the present example.

FIG. 3D shows an example of the manufacturing method for the nitride semiconductor device 100 of the present example.

FIG. 4 shows a modified example of the manufacturing method for the nitride semiconductor device 100 of the present example.

FIG. 5 shows a modified example of the manufacturing method for the nitride semiconductor device 100 of the present example.

FIG. 6A shows a distribution of a Ga concentration inside a protective film 30 and a nitride semiconductor layer 25, in the manufacturing method of a comparative example.

FIG. 6B shows a distribution of a Ga concentration inside the protective film 30 and the nitride semiconductor layer 25, in the manufacturing method of the present example.

FIG. 7 shows arithmetic average roughness (Ra) of a front surface 21 of the nitride semiconductor layer 25, after a step S140 of heat treating.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

In the present specification, one side in a direction parallel to a depth direction of a semiconductor substrate is referred to as an “upper” side, and the other side is referred to as a “lower” side. One surface of two principal surfaces of a substrate, a layer, or another member is referred to as an upper surface, and the other surface is referred to as a lower surface. “Upper”, “lower”, “front”, and “back” directions are not limited to a direction of gravity, or a direction of an attachment to a substrate or the like when a semiconductor device is mounted.

In the present specification, in a layer or a region specified with N or P, electrons or holes are meant to be majority carriers, respectively. In addition, the sign “+” or “−” given to the character “N” or “P” means having a higher doping concentration or a lower doping concentration than layers or regions without it, respectively.

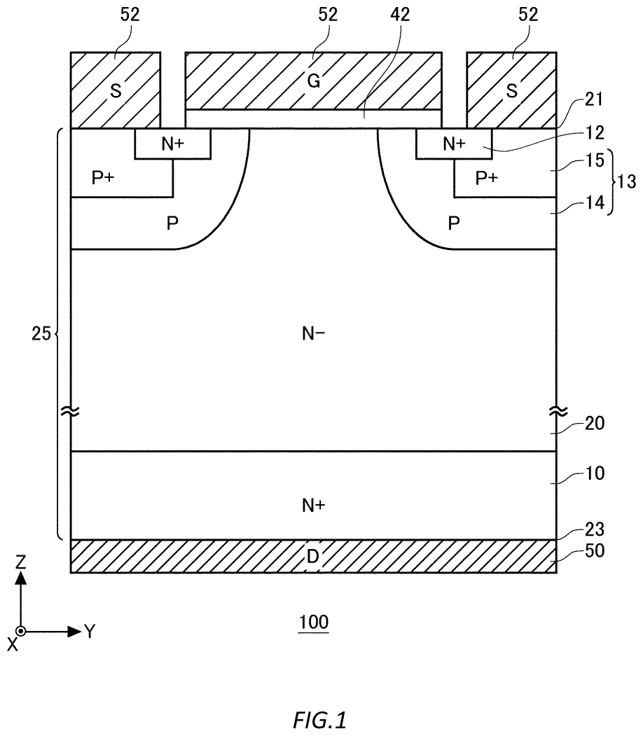

FIG. 1 shows an example of a cross section of an active region of a nitride semiconductor device 100. The active region may be a region through which a main current flows when the nitride semiconductor device 100 is in operation. The active region may have a metal oxide semiconductor field effect transistor (MOSFET) structure. The active region may have a MOSFET structure of a planar gate type, or may have a MOSFET structure of a trench gate type. The active region may have a diode structure.

The nitride semiconductor device 100 of the present example includes a nitride semiconductor layer 25, a gate dielectric film 42, a back surface side electrode 50, and a front surface side electrode 52. The nitride semiconductor layer 25 includes a semiconductor substrate 10, an epitaxial region 20, and a region 12 of an N type and a region 13 of a P type which are provided in the epitaxial region 20. The region 13 of the P type includes a body region 14 and a contact region 15.

The semiconductor substrate 10 is a semiconductor substrate of an N+ type. The semiconductor substrate 10 may be a GaN substrate, or may be a Si substrate. The semiconductor substrate 10 may be prepared using any method, such as a vapor phase epitaxy such as hydride vapor phase epitaxy (HVPE), or liquid phase epitaxy. The semiconductor substrate 10 may be cut out from a GaN layer that is epitaxially grown.

The epitaxial region 20 is provided above the semiconductor substrate 10. The epitaxial region 20 is provided on the semiconductor substrate 10 by being epitaxially grown thereon. For example, the epitaxial region 20 is a material that is able to be epitaxially grown on the semiconductor substrate 10 of GaN or the like. The epitaxial region 20 may be of the N type, or may be of an I type. The I type refers to an intrinsic semiconductor with no dopants implanted. The epitaxial region 20 of the present example is of an N-type with a lower doping concentration than that of the semiconductor substrate 10. For example, the doping concentration of the epitaxial region 20 is 1E16 cm⁻³. A thickness of the epitaxial region 20 is not particularly limited, but as an example, is 10 μm.

The region 12 of the N type is a region of the N+ type provided on a front surface 21 side of the epitaxial region 20. The region 12 of the N type of the present example is provided between a gate electrode G and a source electrode S, on the front surface side electrode 52. The region 12 of the N type may function as a source region of the nitride semiconductor device 100.

The doping concentration of the region 12 of the N type is higher than the doping concentration of the epitaxial region 20. The doping concentration of the region 12 of the N type may be higher than the doping concentration of the semiconductor substrate 10. In an example, the doping concentration of the region 12 of the N type is 1E18 cm⁻³ or higher and 1E21 cm⁻³ or lower.

The region 12 of the N type may be provided by ion implantation of the dopant of the N type into the epitaxial region 20. For example, the dopant of the N type is at least one of silicon (Si), oxygen (O), or germanium (Ge).

The region 13 of the P type is a region of the P type provided in the epitaxial region 20. The region 13 of the P type of the present example includes the body region 14 and the contact region 15. Each of the body region 14 and the contact region 15 is formed by ion implantation of the dopant of the P type into the epitaxial region.

The body region 14 is provided on the epitaxial region 20. The body region 14 is provided by the ion implantation of the dopant into the epitaxial region 20. A conductivity type of the body region 14 of the present example is the P type. For example, the dopant of the P type is at least one of magnesium (Mg) or beryllium (Be). The dopant of the P type may be calcium (Ca) or zinc (Zn).

The body region 14 of the present example is selectively provided in the epitaxial region 20. The expression of being selectively provided refers to being provided on a part of the upper surface, rather than being provided on the entire upper surface of the epitaxial region 20. For example, the ion implantation of the dopant of the P type is performed onto the epitaxial region 20 using a mask with a predetermined pattern.

The doping concentration of the dopant of the P type in the body region 14 may be 1E19 cm⁻³ or lower. The doping concentration of the dopant of the P type in the body region 14 may be 1E16 cm⁻³ or higher, may be 1E17 cm⁻³ or higher, or may be 1E18 cm⁻³ or higher.

The contact region 15 is provided in contact with the front surface side electrode 52 above the epitaxial region 20. The contact region 15 is provided by the ion implantation of the dopant into the epitaxial region 20. The conductivity type of the contact region 15 of the present example is of a P+ type.

The dopant of the P type which is included in the contact region 15 may be the same as or may be different from the dopant of the P type which is included in the body region 14. The doping concentration of the contact region 15 is greater than the doping concentration of the body region 14. In an example, the doping concentration of the contact region 15 is 1E18 cm⁻³ or higher and 1E21 cm⁻³ or lower.

The front surface side electrode 52 is provided above the nitride semiconductor layer 25. The front surface side electrode 52 includes the gate electrode G and the source electrode S. The front surface side electrode 52 is formed of a material containing metal. At least a part of a region of the front surface side electrode 52 may be formed of metal such as aluminum (Al), or an alloy containing aluminum, for example, a metal alloy such as an aluminum-silicon alloy (AlSi) and an aluminum-silicon-copper alloy (AlSiCu).

The back surface side electrode 50 is provided in contact with the back surface 23. The back surface side electrode 50 includes a drain electrode D. The back surface side electrode 50 is formed of a material containing metal. The back surface side electrode 50 may be formed of the same material as that of the front surface side electrode 52, or may be formed of a different material.

The gate dielectric film 42 is provided between a channel region above the epitaxial region 20 and the gate electrode G. By a voltage being applied from the gate electrode G via the gate dielectric film 42, the main current flows between the source electrode S and the drain electrode D.

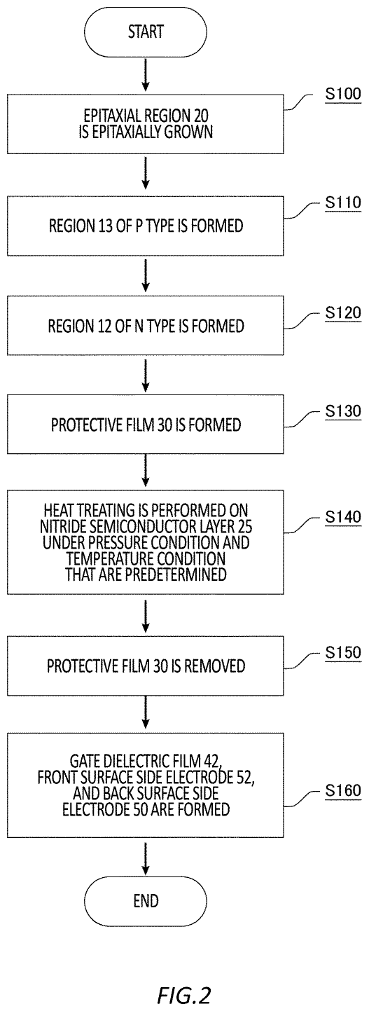

FIG. 2 is a flowchart showing an example of a manufacturing method for the nitride semiconductor device 100 of the present example. The manufacturing method for the nitride semiconductor device 100 may include a step S100 of epitaxially growing the epitaxial region 20 above the semiconductor substrate 10. In the step S100, the epitaxial region 20 is formed above the semiconductor substrate 10. The epitaxial region 20 of the present example is epitaxially grown above the semiconductor substrate 10 using any method such as metal organic chemical vapor deposition (MOCVD).

The manufacturing method for the nitride semiconductor device 100 may include a step S110 of forming the region 13 of the P type in the epitaxial region 20. In the step S110, the region 13 of the P type is formed in at least a part of the nitride semiconductor layer 25. The region 13 of the P type includes the body region 14 and the contact region 15. The region 13 of the P type may contain at least one of magnesium (Mg) or beryllium (Be).

The manufacturing method for the nitride semiconductor device 100 may include a step S120 of forming the region 12 of the N type in the epitaxial region 20. In the step S120, the region 12 of the N type is formed in at least a part of the nitride semiconductor layer 25. The region 12 of the N type may contain at least any of silicon (Si), oxygen (O), or germanium (Ge).

The manufacturing method for the nitride semiconductor device 100 of the present example includes a step S130 of forming a protective film 30 above the nitride semiconductor layer 25. In the step S130, the protective film 30 is provided above the nitride semiconductor layer 25. The protective film 30 of the present example is an amorphous protective film containing silicon. The protective film 30 will be described in detail below.

The manufacturing method for the nitride semiconductor device 100 of the present example includes a step S140 of performing heat treating on the nitride semiconductor layer 25 under a pressure condition and a temperature condition that are predetermined. In the step S140, the heat treating is performed on the nitride semiconductor layer 25 provided with the protective film 30. In the step S140, the heat treating is performed on the nitride semiconductor layer 25 under the pressure condition and the temperature condition that are predetermined. The predetermined pressure condition is, in an example, a pressure condition of 1 MPa or higher and 1 GPa or lower. The predetermined temperature condition is, in an example, a temperature condition of 1200° C. or higher and 1500° C. or lower. The temperature condition may be the same as that of 1200° C., or may be a temperature higher than 1200° C.

The manufacturing method for the nitride semiconductor device 100 may include a step S150 of removing the protective film 30. After the step S140 of the heat treating, the protective film 30 is removed in the step S150. The protective film 30 may be removed by cleaning with a liquid agent corresponding to the material of the protective film 30. As an example, when the protective film 30 is an AlN film, it is possible to selectively remove the protective film 30 by using a potassium hydroxide solution. In a case where the protective film 30 is an amorphous protective film containing silicon, as an example, in a case of a SiO₂ film, it is possible to selectively remove the protective film 30 by using an aqueous solution of hydrofluoric acid.

The manufacturing method for the nitride semiconductor device 100 may include a step S160 of forming the gate dielectric film 42, the front surface side electrode 52, and the back surface side electrode 50. In the step S160, the gate dielectric film 42, the front surface side electrode 52, and the back surface side electrode 50 are formed. The front surface side electrode 52 includes the gate electrode G and the source electrode S. The back surface side electrode 50 includes the drain electrode D.

The manufacturing method for the nitride semiconductor device 100 of the present example is not limited to the example shown in FIG. 2. The manufacturing method for the nitride semiconductor device 100 may include a step other than each step shown in FIG. 2. The manufacturing method for the nitride semiconductor device 100 may include a dehydrogenation annealing step for removing hydrogen contained in the nitride semiconductor layer 25, and may include an additional annealing step for performing hard baking on the gate dielectric film 42. The maximum temperature in these annealing steps is lower than the maximum temperature in the step S140 of the heat treating.

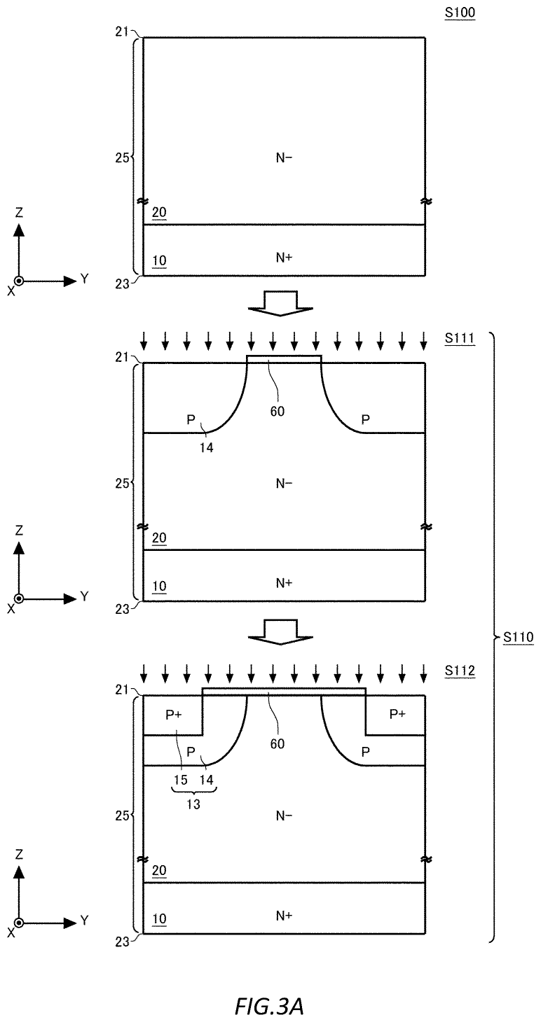

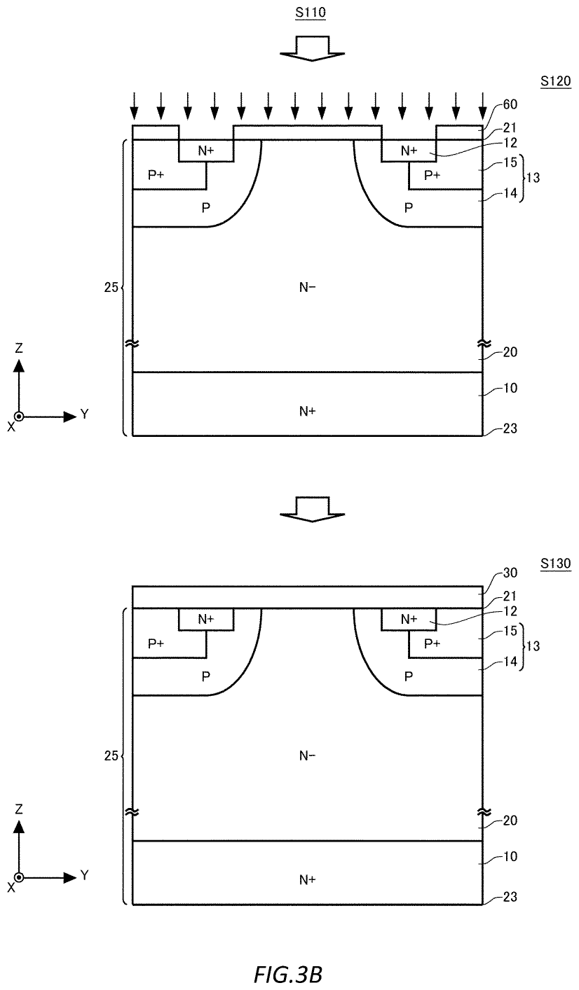

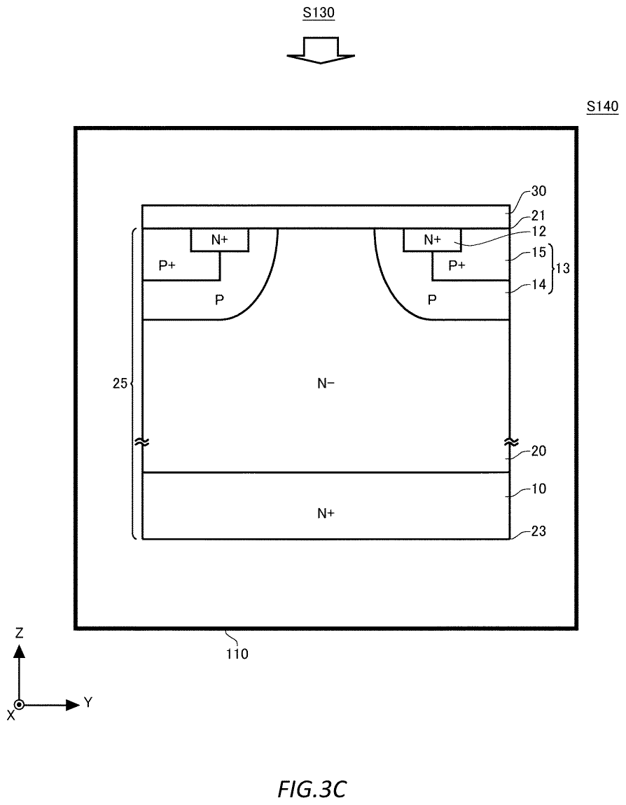

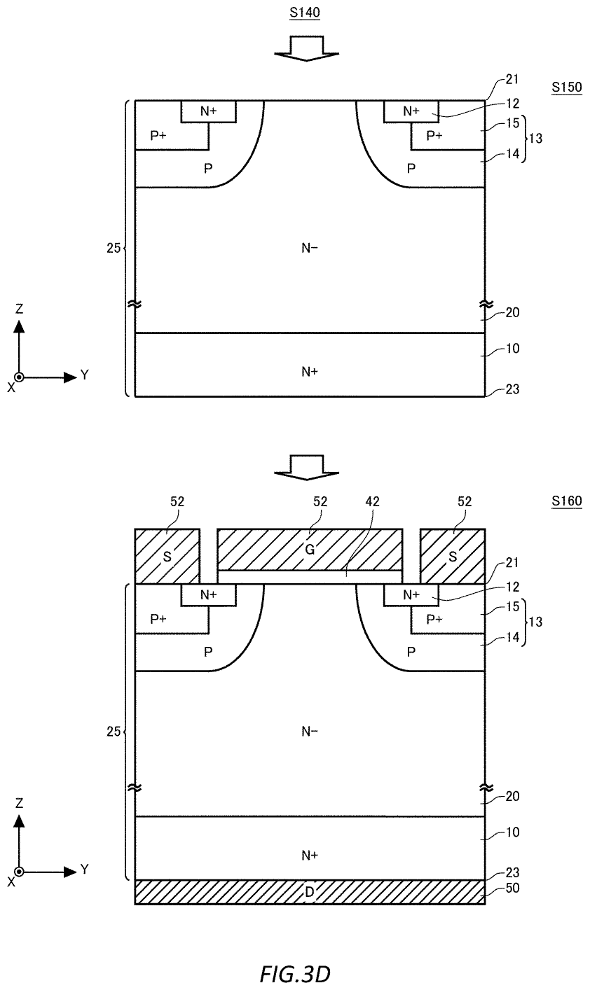

FIG. 3A shows an example of a manufacturing method for the nitride semiconductor device 100 of the present example. With reference to FIG. 3A, the step S100 to the step S110 will be described in detail.

In the present example, in the step S100, GaN which is a nitride semiconductor is epitaxially grown on the semiconductor substrate 10. The epitaxial growth may be performed by the MOCVD in which a raw material gas containing trimethylgallium (Ga(CH₃)₃), ammonia (NH₃), and monosilane (SiH₄), and a pressurized gas containing nitrogen (N₂) and hydrogen (H₂) are caused to flow on the semiconductor substrate 10. In this case, silicon (Si) of monosilane functions as the dopant of the N type in the epitaxial region 20. The semiconductor substrate 10 of the present example is a GaN substrate; however, a silicon carbide (SiC) substrate, or a zirconium boride (ZrB₂) substrate, or the like may also be used. In addition, instead of the MOCVD, the HVPE or molecular beam epitaxy (MBE) may be used.

In the step S110, the region 13 of the P type is formed. In the step S110, the region 13 of the P type is formed by selectively performing the ion implantation of the dopant of the P type into the nitride semiconductor layer 25. The step S110 of the present example includes a step S111 of forming the body region 14, and a step S112 of forming the contact region 15.

In the step S111, the body region 14 is formed. The body region 14 is selectively formed in at least a part of the nitride semiconductor layer 25. In the step S111, a mask 60 is formed on the front surface 21 of the epitaxial region 20, and then the ion implantation of the dopant of the P type is performed using the mask 60. This makes it possible to selectively form the body region 14.

The dopant of the P type which is implanted in the step S111 may be magnesium (Mg) or beryllium (Be). The dopant of the P type may be implanted by multi-stage implantations in which a dose and an acceleration voltage are changed. This makes it possible to adjust the doping concentration of the body region 14 after the heat treating in the step S140.

In the step S112, the contact region 15 is formed. The contact region 15 is selectively formed in at least a part of the nitride semiconductor layer 25. In the step S112, the mask 60 formed in the step S111 may be removed, and the mask 60 may be newly formed in a region different from the region in which the mask 60 is formed in the step S111. This makes it possible for the contact region 15 to be selectively formed in a region different from the region in which the body region 14 is formed.

Each of the type, the dose, and the acceleration voltage of the dopant of the P type which is implanted in the step S112 may be the same as or different from that in the step S111. When both of the body region 14 and the contact region 15 are formed by multi-stage dopant implantations, the number of times of dopant implantations may be the same, or may be different. This makes it possible to adjust the doping concentration of the contact region 15 after the heat treating in the step S140.

FIG. 3B shows an example of the manufacturing method for the nitride semiconductor device 100 of the present example. FIG. 3B is a continuation of the step S110 described in FIG. 3A. The step S120 to the step S130 will be described in detail with reference to FIG. 3B.

In the step S120, the region 12 of the N type is formed. The region 12 of the N type is selectively formed in at least a part of the nitride semiconductor layer 25. In the step S120, the mask 60 formed in the step S112 may be removed, and the mask 60 may be newly formed in a region different from the region in which the mask 60 is formed in the step S112. This makes it possible for the region 12 of the N type to be selectively formed in a region different from the region in which the region 13 of the P type is formed. The region 12 of the N type of the present example is formed between the regions in which the gate electrode G and the source electrode S are to be formed later.

The dopant of the N type which is implanted in the step S120 may be silicon (Si), oxygen (O), or germanium (Ge). The dopant of the N type may be implanted by multi-stage implantations in which a dose and an acceleration voltage are changed. This makes it possible to adjust the doping concentration of the region 12 of the N type after the heat treating in the step S140.

In the step S130, the protective film 30 is formed. The protective film 30 is in contact with the nitride semiconductor layer 25. That is, the protective film 30 is formed in direct contact with the front surface 21 of the epitaxial region 20. In the present example, in the step S110 and the step S120, by the ion implantations of the dopants of the P type and the N type, each of the region 13 of the P type and the region 12 of the N type is formed, and thus crystallinity on the front surface 21 of the epitaxial region 20 is disturbed. In this manner, in comparison with a case where each region is formed by the epitaxial growth rather than the ion implantation, the epitaxial region 20 is more easily decomposed and a nitrogen atom (N) is more easily released from the epitaxial region 20. In the present example, the protective film 30 is in contact with the nitride semiconductor layer 25, and thus it is possible to reduce the decomposition of the epitaxial region 20 and the release of N in the step S140 of the heat treating described below.

The protective film 30 is an amorphous protective film containing silicon. The material of the protective film 30 is an amorphous material that is not crystallized under the temperature condition of the step S140 of the heat treating. The expression that the protective film 30 is not crystallized may mean that the protective film 30 does not have an observable crystalline phase under the temperature conditions of the step S140 of the heat treating. The material of the protective film 30 may be a material which has a high heat resistance, and good adhesion to the epitaxial region 20, and by which an impurity is not diffused from the protective film 30 to the epitaxial region 20. The material of the protective film 30 may be a material which has etch selectivity with respect to the epitaxial region 20. The protective film 30 of the present example contains at least one of SiO₂, SiN, or SiON.

The protective film 30 may be formed by a sputtering method, or may be formed by chemical vapor deposition such as plasma chemical vapor deposition (plasma CVD), low pressure chemical vapor deposition (LPCVD), or mist chemical vapor deposition (mist CVD). The protective film 30 may be formed by a method of a combination of the formation by the sputtering method and the formation by the chemical vapor deposition.

The protective film 30 may have a single layer. The expression that the protective film 30 has a single layer may mean that the protective film 30 is formed by a single material, or may mean that the protective film 30 is formed by a single method.

The thickness of the protective film 30 of the present example is 10 nm or more and 500 nm or less. The protective film 30 of the present example is an amorphous film containing silicon, and thus is not crystallized even in the step S140 of the heat treating described below, and the thickness thereof does not become thin more easily in comparison with a material that is crystallized. This makes it possible to more precisely control the thickness of the protective film 30, in comparison with a case where a material that is crystallized is used for the protective film 30. In an example, the thickness of the protective film 30 is 10 nm or more and 50 nm or less.

FIG. 3C shows an example of the manufacturing method for the nitride semiconductor device 100 of the present example. FIG. 3C is a continuation of the step S130 described in FIG. 3B. The Step S140 will be described in detail with reference to FIG. 3C.

In the step S140, the heat treating is performed on the nitride semiconductor layer 25 provided with the protective film 30. In the step S140 of the present example, the nitride semiconductor layer 25 is arranged in a hot isostatic pressing apparatus (Hot Isostatic Pressing Apparatus) 110. Then, an initial pressure calculated to obtain a desired pressure at a heat treating temperature that is set as s target, is applied to a treatment chamber in the hot isostatic pressing apparatus 110, and then the temperature is raised in a sealed state, thereby raising the pressure in the treatment chamber by a thermal expansion of the gas. In this manner, the treatment chamber is maintained at a temperature and a pressure that are predetermined, to perform the heat treating on the nitride semiconductor layer 25. The heat treating of the present example means annealing the nitride semiconductor layer 25 provided with the protective film 30 for a certain period of time under the pressure condition and the temperature condition that are predetermined.

In the manufacturing method for the nitride semiconductor device 100 of the present example, the heat treating is performed on the nitride semiconductor layer 25 provided with the amorphous protective film 30 containing silicon, under the pressure condition of 1 MPa or higher and 1 GPa or lower, and under the temperature condition of 1200° C. or higher and 1500° C. or lower. The temperature condition of 1200° C. or higher and 1500° C. or lower may mean that the maximum temperature in the step S140 of the heat treating is included in the temperature range. The temperature in the step S140 of the heat treating may be 1250° C. or higher and 1400° C. or lower.

The pressure condition of 1 MPa or higher and 1 GPa or lower may mean that the pressure inside the hot isostatic pressing apparatus 110 at the maximum temperature in the step S140 of the heat treating is included in the pressure range. The pressure in the step S140 of the heat treating may be 10 MPa or higher and 500 MPa or lower. The pressure in the step S140 of the heat treating may be 100 MPa or higher and 500 MPa or lower.

The pressure condition in the step S140 of the heat treating may be changed according to the temperature condition. As an example, the pressure in the step S140 of the heat treating is 0.1% or higher and 1000% or lower of an equilibrium vapor pressure of the nitride semiconductor layer 25. The equilibrium vapor pressure of the nitride semiconductor layer 25 means a pressure at which N can be prevented from being decomposed and being released from the nitride semiconductor layer 25 under a predetermined temperature condition.

In the manufacturing method for the nitride semiconductor device 100 of the present example, by using the protective film 30 which is an amorphous film containing silicon, and by pressing the protective film 30 with an atmospheric gas, it is possible to suppress the decomposition of the nitride semiconductor layer 25, even under the pressure condition equal to or lower than the equilibrium vapor pressure of the nitride semiconductor layer 25. The pressure in the step S140 of the heat treating may be 0.3% or higher and 400% or lower of the equilibrium vapor pressure of the nitride semiconductor layer 25, or may be 3% or higher and 200% or lower.

The pressure in the step S140 of the heat treating may be equal to or higher than the equilibrium vapor pressure of the nitride semiconductor layer 25. As an example, the equilibrium vapor pressure of the nitride semiconductor layer 25 at 1300° C. is about 300 MPa, and thus the temperature condition and the pressure condition in the step S140 of the heat treating are 1300° C. and 300 MPa, respectively. The temperature condition and the pressure conditions in the step S140 of the heat treating may be 1300° C. and 500 MPa, respectively. By setting the pressure condition to be equal to or higher than the equilibrium vapor pressure of the nitride semiconductor layer 25, it is possible to suppress the decomposition of the nitride semiconductor layer 25 in the step S140 of the heat treating.

In the step S140 of the heat treating, the period of time during which the temperature of the nitride semiconductor layer 25 is maintained at 1200° C. or higher and 1500° C. or lower, may be 30 minutes or more and 60 minutes or less. In the manufacturing method for the nitride semiconductor device 100 of the present example, by using the protective film 30 which is an amorphous film containing silicon, it is possible to suppress the decomposition of the nitride semiconductor layer 25 even when the heat treating is performed for 30 minutes or more.

FIG. 3D shows an example of the manufacturing method for the nitride semiconductor device 100 of the present example. FIG. 3D is a continuation of the step S140 described in FIG. 3C. The step S150 and the step S160 will be described in detail with reference to FIG. 3D.

After the step S140 of the heat treating, the protective film 30 is removed in the step S150. The material of the protective film 30 is constituted by a material that has etch selectivity with respect to the epitaxial region 20, and thus it is possible to selectively remove only the protective film 30 without damaging the epitaxial region 20.

In the step S160, by applying a film formation method and a patterning method that are known, the gate dielectric film 42, the front surface side electrode 52, and the back surface side electrode 50 are formed. The SiO₂ film as the gate dielectric film 42 may be formed by the chemical vapor deposition method described above. The thickness of the gate dielectric film 42 is 100 nm, for example. It should be noted that the gate dielectric film 42 may be a silicon oxynitride (SiON) film, an aluminum oxide (Al₂O₃) film, an aluminum oxynitride (AlON) film, a magnesium oxide (MgO) film, a gallium oxide (GaOₓ) film, a gadolinium oxide (GdOₓ) film, or a stacked film containing two or more types of these, instead of the SiO₂ film.

After that, as the gate electrode G of the front surface side electrode 52, polycrystalline silicon may be formed by LPCVD. During film formation or after film formation of polycrystalline silicon, the polycrystalline silicon may be doped by one or more types of elements of phosphorus (P) and arsenic (As). This makes it possible for the polycrystalline silicon to have an enhanced conductivity. It should be noted that as the gate electrode G, a metal film of any of gold (Au), platinum (Pt), nickel (Ni), aluminum (Al), titanium (Ti), and tungsten (W), or an alloy film of these may be used; or a ceramic film or a silicide film such as titanium nitride (TiN), tungsten silicide (WSi), or nickel silicide (NiSi) may be used. By photolithography and etching, the gate dielectric film 42 and the gate electrode G are patterned.

After that, the source electrode S of the front surface side electrode 52 is formed. The source electrode S may be a stacked body having a Ti (titanium) layer for a lower layer and an Al layer for an upper layer. It should be noted that in order to reduce a contact resistance between the source electrode S and the contact region 15, the contact region 15 may contain Ni (nickel), Pd (palladium), or Pt (platinum) at an interface with the source electrode S. After that, the drain electrode D of the back surface side electrode 50 is formed. The drain electrode D may be a stacked body having a Ti layer for an upper layer in direct contact with the back surface 23 of the semiconductor substrate 10 and an Al layer for a lower layer.

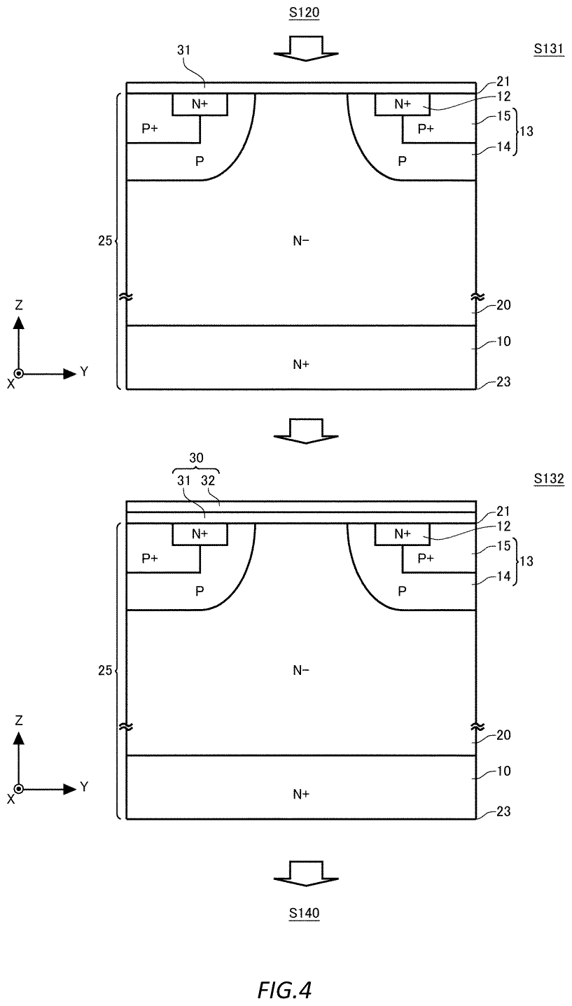

FIG. 4 shows a modified example of the manufacturing method for the nitride semiconductor device 100 of the present example. FIG. 4 is a continuation of the step S120 described in FIG. 3B. A modified example of step S130 of providing the protective film 30 will be described with reference to FIG. 4.

The step S130 of providing the protective film 30 may include step S131 of providing a first protective layer 31 in contact with the nitride semiconductor layer 25, and step S132 of providing a second protective layer 32 containing a material different from that of the first protective layer 31, above the first protective layer 31. The protective film 30 of the present example includes the first protective layer 31 and the second protective layer 32. The step S130 of providing the protective film 30 may include providing an additional protective layer above the second protective layer 32. That is, the protective film 30 may include protective layers constituted by three or more materials that are different from each other.

In the step S131, the first protective layer 31 in contact with the nitride semiconductor layer 25 is formed. The first protective layer 31 is a protective layer of an amorphous film containing silicon. The first protective layer 31 of the present example contains at least one of SiO₂, SiN, or SiON. By forming the first protective layer 31 as an amorphous film containing silicon, it is possible to suppress the decomposition of the nitride semiconductor layer 25 in the step S140 of the heat treating.

In the step S132, the second protective layer 32 containing a material different from that of the first protective layer 31 is formed, above the first protective layer 31. The second protective layer 32 may be an amorphous film containing silicon, or may be an amorphous film other than that. The second protective layer 32 of the present example contains at least one of SiO₂, SiN, SiON, AlN, Al₂O₃, or AlGaN. This makes it possible to enhance the stability of the protective film 30.

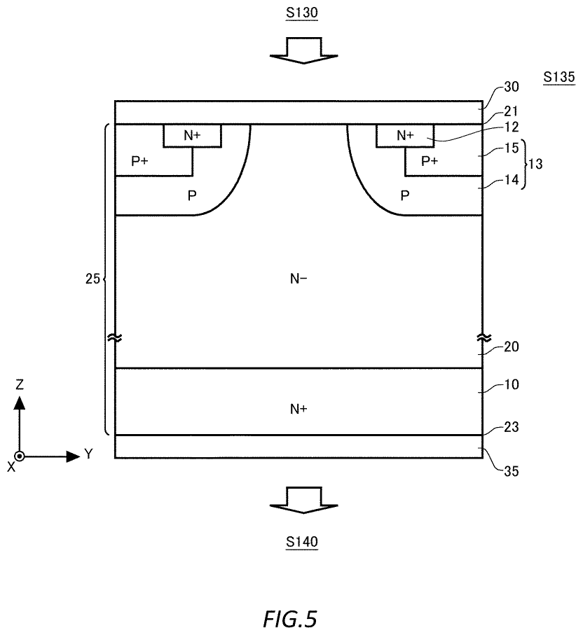

FIG. 5 shows a modified example of the manufacturing method for the nitride semiconductor device 100 of the present example. FIG. 5 is a continuation of the step S130 described in FIG. 3B.

The manufacturing method for the nitride semiconductor device 100 of the present example includes a step S135 of forming a protective film 35 on the back surface 23 of the nitride semiconductor layer 25. This makes it possible to suppress the decomposition of the nitride semiconductor layer 25 on a back surface 23 side in step S140 of the heat treating.

It should be noted that the step S135 may be omitted. In the manufacturing method for the nitride semiconductor device 100 of the present example, the protective film 30 is provided on the front surface 21 side of the nitride semiconductor layer 25. The front surface 21 of the nitride semiconductor layer 25 of the present example is a Ga surface. In the manufacturing method for the nitride semiconductor device 100 of the present example, the protective film 30 is provided on the front surface 21 side, the front surface 21 being the Ga surface in which the thermal decomposition is easier, thereby making it possible to suppress the decomposition of the nitride semiconductor layer 25 in the step S140 of the heat treating.

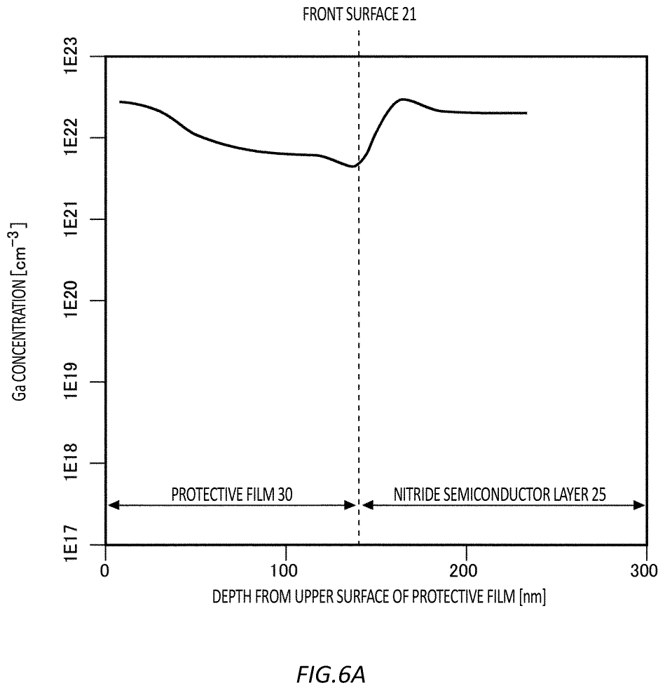

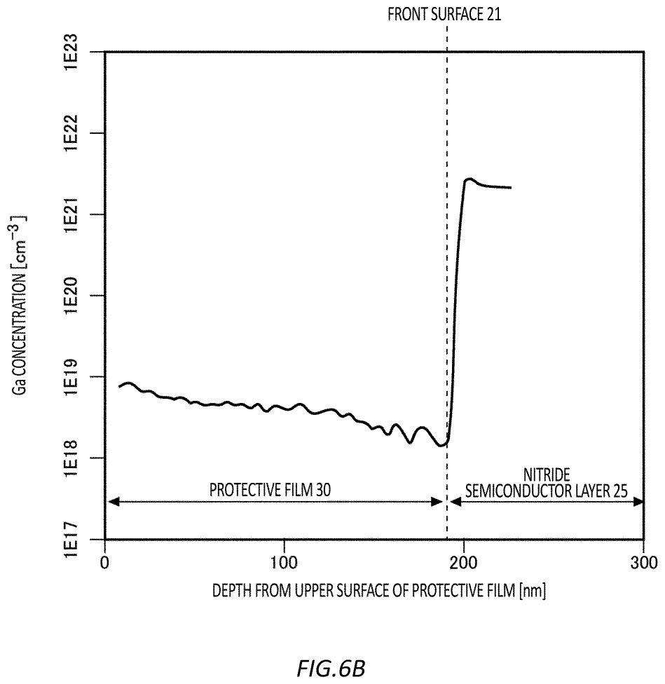

FIG. 6A shows a distribution of a Ga concentration inside the protective film 30 and the nitride semiconductor layer 25, when the manufacturing method for the nitride semiconductor device 100 of a comparative example is used. FIG. 6A shows, as a comparative example, the distribution of the Ga concentration after the step S140 of the heat treating in a case where the protective film 30 is formed of AlN. FIG. 6A is a semi-logarithmic graph in which the horizontal axis represents a depth measured from the upper surface of the protective film 30 and the vertical axis represents the Ga concentration. A region from a position at a depth of 0 nm to the front surface 21 indicated by the dotted line is an inside of the protective film 30, and a region on a right side from the dotted line is an inside of the nitride semiconductor layer 25.

In the comparative example, the protective film 30 was formed of AlN, and then the nitride semiconductor layer 25 was annealed for 60 minutes under the temperature condition of 1300° C. and the pressure condition of 500 MPa in the step S140 of the heat treating. It should be noted that the equilibrium vapor pressure of the nitride semiconductor layer 25 at 1300° C. is about 300 MPa. It can be seen from FIG. 6A that Ga is distributed by the concentration of about 1E22 cm⁻³ in both of the inside of the protective film 30 and the inside of the nitride semiconductor layer 25. This suggests that regardless of the pressure condition being equal to or higher than the equilibrium vapor pressure, the nitride semiconductor layer 25 was thermally decomposed, and Ga generated by the decomposition was diffused into the protective film 30.

FIG. 6B shows a distribution of a Ga concentration inside the protective film 30 and the nitride semiconductor layer 25, when the manufacturing method for the nitride semiconductor device 100 of the present example is used. FIG. 6B shows the distribution of the Ga concentration after the step S140 of the heat treating in a case where the protective film 30 is formed of SiO₂. The axes and the dotted lines are respectively the same as those in FIG. 6A, and therefore the description thereof will be omitted.

In the example of FIG. 6B as well, the protective film was formed of SiO₂, and then similar to FIG. 6A, the nitride semiconductor layer 25 was annealed for 60 minutes under the temperature condition of 1300° C. and the pressure condition of 500 MPa in the step S140 of the heat treating. Unlike the comparative example of FIG. 6A, in the example of FIG. 6B, the Ga concentration inside the protective film 30 is 1E19 cm⁻³ or lower, and a difference in the Ga concentration occurs by about 100 times to 1000 times in comparison with that inside the nitride semiconductor layer 25. This suggests that with the manufacturing method for the nitride semiconductor device 100 of the present example, the thermal decomposition of the nitride semiconductor layer 25 is suppressed in the step S140 of the heat treating.

It should be noted that in both of the examples shown in FIG. 6A and FIG. 6B, regardless of whether the thicknesses of the protective film 30 before the step S140 of the heat treating are set to be the same, the thicknesses are different from each other after the step S140 of the heat treating. This is because the amorphous film which is used in the present example is not crystallized in the step S140 of the heat treating, and in contrast with this, the protective film of AlN or the like which is used in the comparative example is crystallized in the step S140 of the heat treating. In this way, the protective film 30 which is used in the manufacturing method for the nitride semiconductor device 100 of the present example is not crystallized in the step S140 of the heat treating, and thus it is possible to more precisely control the thickness of the protective film 30 in comparison with the case where a material that is crystallized is used.

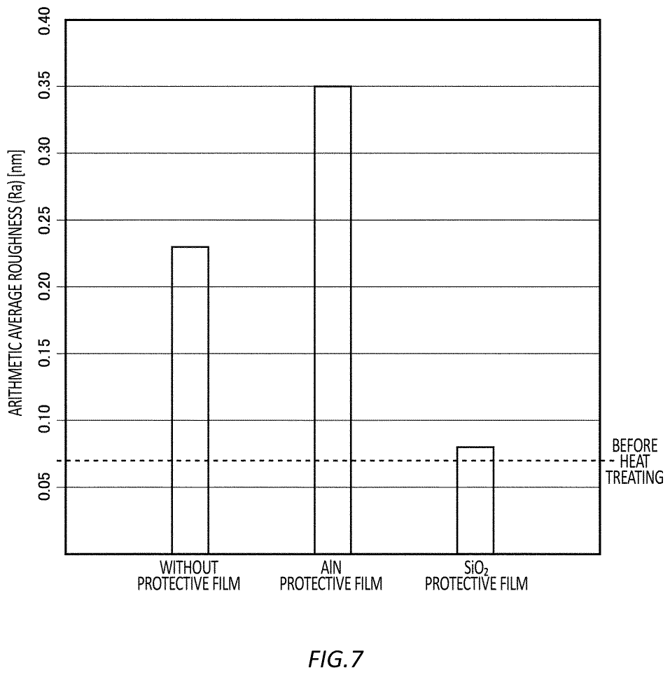

FIG. 7 shows arithmetic average roughness (Ra) of the front surface 21 of the nitride semiconductor layer 25, after a step S140 of heat treating. The data indicated by the dotted line is the arithmetic average roughness (Ra) on the front surface 21 of the nitride semiconductor layer 25 before the step S140 of the heat treating. Before the step S140 of the heat treating, the arithmetic average roughness (Ra) on the front surface 21 of the nitride semiconductor layer 25 is 0.07 nm. In the manufacturing method for the nitride semiconductor device 100 of the present example, in comparison with a case where the protective film 30 was not used or a case where the protective film of AlN was used as the protective film 30, it is possible to suppress the decomposition of the nitride semiconductor layer 25 in the step S140 of the heat treating.

The data for which “without the protective film” is described in FIG. 7 is the arithmetic average roughness (Ra) on the front surface 21 of the nitride semiconductor layer 25, after the step S140 of the heat treating is performed without using the protective film 30 as the comparative example. In the comparative example, the protective film 30 was not provided on the front surface 21 of the nitride semiconductor layer 25, and under the temperature condition of 1300° C. and the pressure condition of 500 MPa, the nitride semiconductor layer 25 was annealed for 60 minutes. It can be seen that the arithmetic average roughness (Ra) is increased in comparison with the state before the heat treating. After the step S140 of the heat treating is performed without using the protective film 30, the arithmetic average roughness (Ra) on the front surface 21 of the nitride semiconductor layer 25 is 0.23 nm.

The data for which the “AlN protective film” is described in FIG. 7 is the arithmetic average roughness (Ra) on the front surface 21 of the nitride semiconductor layer 25, after the step S140 of the heat treating is performed using the protective film 30 which is constituted by AlN as the comparative example. In the comparative example, the protective film 30 of AlN was provided on the front surface 21 of the nitride semiconductor layer 25, and under the temperature condition of 1300° C. and the pressure condition of 500 MPa, the nitride semiconductor layer 25 was annealed for 60 minutes. With reference to FIG. 7, it can be seen that even when the protective film 30 of AlN is used, the arithmetic average roughness (Ra) is increased in comparison with the state before the heat treating. After the step S140 of the heat treating is performed using the AlN protective film, the arithmetic average roughness (Ra) on the front surface 21 of the nitride semiconductor layer 25 is 0.35 nm.

The data for which the “SiO₂ protective film” is described in FIG. 7 is the arithmetic average roughness (Ra) on the front surface 21 of the nitride semiconductor layer 25, after the step S140 of the heat treating is performed in the manufacturing method for the nitride semiconductor device 100 of the present example. In the present example, the protective film 30 of SiO₂ was provided on the front surface 21 of the nitride semiconductor layer 25, and under the temperature condition of 1300° C. and the pressure condition of 500 MPa, the nitride semiconductor layer 25 was annealed for 60 minutes. With reference to FIG. 7, the arithmetic average roughness (Ra) is increased slightly in comparison with the state before the heat treating; however, an amount of the increase is smaller than those in the comparative examples of “without the protective film” and the “AlN protective film”. In the present example, the arithmetic average roughness (Ra) on the front surface 21 of the nitride semiconductor layer 25 is 0.08 nm.

As shown in FIG. 7, in the manufacturing method for the nitride semiconductor device 100 of the present example, by using the amorphous protective film 30 containing silicon, it is possible to suppress the decomposition of the nitride semiconductor layer 25 in the step S140 of the heat treating. In the manufacturing method for the nitride semiconductor device 100 of the present example, after the step S140 of the heat treating, the arithmetic average roughness (Ra) on the front surface 21 of the nitride semiconductor layer 25 is 0.01 nm or higher and 0.2 nm or lower.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate; 12: region of N type; 13: region of P type; 14: body region; 15: contact region; 20: epitaxial region; 21: front surface; 23: back surface; 25: nitride semiconductor layer; 30: protective film; 31: first protective layer; 32: second protective layer; 35: protective film; 42: gate dielectric film; 50: back surface side electrode; 52: front surface side electrode; 60: mask; 100: nitride semiconductor device; 110: hot isostatic pressing apparatus.

What is claimed is:

1. A manufacturing method for a nitride semiconductor device comprising:
providing an amorphous protective film containing silicon above a nitride semiconductor layer; and
performing heat treating on the nitride semiconductor layer provided with the protective film, under a pressure condition of 1 MPa or higher and 1 GPa or lower, and under a temperature condition of 1200° C. or higher and 1500° C. or lower.

2. The manufacturing method for the nitride semiconductor device according to claim 1, wherein
the protective film is in contact with the nitride semiconductor layer.

3. The manufacturing method for the nitride semiconductor device according to claim 1, wherein
the protective film contains at least one of SiO₂, SiN, or SiON.

4. The manufacturing method for the nitride semiconductor device according to claim 1, wherein
the protective film has a single layer.

5. The manufacturing method for the nitride semiconductor device according to claim 1, wherein
the providing the protective film includes
providing a first protective layer in contact with the nitride semiconductor layer, and
providing a second protective layer containing a material different from that of the first protective layer, above the first protective layer.

6. The manufacturing method for the nitride semiconductor device according to claim 5, wherein
the first protective layer contains at least one of SiO₂, SiN, or SiON.

7. The manufacturing method for the nitride semiconductor device according to claim 5, wherein
the second protective layer contains at least one of SiO₂, SiN, SiON, AlN, Al₂O₃, or AlGaN.

8. The manufacturing method for the nitride semiconductor device according to claim 1, wherein
a thickness of the protective film is 10 nm or more and 500 nm or less.

9. The manufacturing method for the nitride semiconductor device according to claim 1, wherein
a thickness of the protective film is 10 nm or more and 50 nm or less.

10. The manufacturing method for the nitride semiconductor device according to claim 1, wherein
a pressure in the performing the heat treating is 0.1% or higher and 1000% or lower of an equilibrium vapor pressure of the nitride semiconductor layer.

11. The manufacturing method for the nitride semiconductor device according to claim 1, wherein
a pressure in the heat treating is equal to or higher than an equilibrium vapor pressure of the nitride semiconductor layer.

12. The manufacturing method for the nitride semiconductor device according to claim 1, wherein
a pressure in the heat treating is 10 MPa or higher and 500 MPa or lower.

13. The manufacturing method for the nitride semiconductor device according to claim 1, wherein
a pressure in the heat treating is 100 MPa or higher and 500 MPa or lower.

14. The manufacturing method for the nitride semiconductor device according to claim 1, comprising:
forming a region of a P type containing at least one of Mg or Be, in at least a part of the nitride semiconductor layer; and
forming a region of an N type containing at least any of Si, O, or Ge, in at least a part of the nitride semiconductor layer.

15. The manufacturing method for the nitride semiconductor device according to claim 1, wherein
a temperature in the heat treating is 1250° C. or higher and 1400° C. or lower.

16. The manufacturing method for the nitride semiconductor device according to claim 1, wherein
in the heat treating, a period of time during which a temperature of the nitride semiconductor layer is maintained at 1200° C. or higher and 1500° C. or lower is 30 minutes or more and 60 minutes or less.

17. The manufacturing method for the nitride semiconductor device according to claim 1, comprising:
removing the protective film after the heat treating.

18. The manufacturing method for the nitride semiconductor device according to claim 1, wherein
after the heat treating, arithmetic average roughness (Ra) on a front surface of the nitride semiconductor layer is 0.01 nm or higher and 0.2 nm or lower.

19. The manufacturing method for the nitride semiconductor device according to claim 1, wherein
a front surface of the nitride semiconductor layer is a Ga surface.

20. The manufacturing method for the nitride semiconductor device according to claim 1, wherein
in the heat treating, the protective film is not crystallized.
